(19) United States
(12) Patent Application Publication
(10) Pub. No.: US 2025/0210505 A1
(43) Pub. Date: Jun. 26, 2025

(54) STRETCHABLE DEVICE

(71) Applicant: Murata Manufacturing Co., Ltd., Nagaokakyo-shi (JP)

(72) Inventors: Yui NAKAMURA, Nagaokakyo-shi (JP); Toshifumi ASUKAI, Nagaokakyo-shi (JP)

(21) Appl. No.: 19/074,665

(22) Filed: Mar. 10, 2025

Related U.S. Application Data
(63) Continuation of application No. PCT/JP2023/032850, filed on Sep. 8, 2023.

(30) Foreign Application Priority Data
Sep. 28, 2022 (JP) 2022-155142

(51) Int. Cl. H01L 23/498

(52) U.S. Cl. CPC H01L 23/4985; H01L 23/49833; H01L 23/49838

(57) ABSTRACT

A stretchable device that includes: a first substrate having stretchability; a first wiring on a first main surface of the first substrate; a second substrate facing the first substrate in a thickness direction of the first substrate and connected to the first substrate; a second wiring on a first main surface of the second substrate and facing the first wiring in the first direction; and a first protective layer on the first main surface of the first substrate and a second main surface of the second substrate so as to cover at least a part of the first wiring and at least a part of the second substrate, wherein the first wiring and the second wiring are electrically connected in an overlapping region when viewed from the first direction, and the first protective layer overlaps an entirety of the overlapping region when viewed from the first direction.

### CROSS REFERENCE TO RELATED APPLICATIONS

The present application is a continuation of International application No. PCT/JP2023/032850, filed Sep. 8, 2023, which claims priority to Japanese Patent Application No. 2022-155142, filed Sep. 28, 2022, the entire contents of each of which are incorporated herein by reference.

### TECHNICAL FIELD

The present disclosure relates to a stretchable device.

### BACKGROUND ART

Conventionally, as a stretchable device, there is one described in Japanese Patent Application Laid-Open No. 2008-108890 (Patent Document 1). The stretchable device includes a first substrate, a first wiring provided on a first main surface of the first substrate, a second substrate facing the first substrate in a thickness direction of the first substrate, a second wiring provided on the second substrate and facing the first wiring in the thickness direction, and a connection member connecting the first substrate and the second substrate. The first wiring and the second wiring are electrically connected.

### SUMMARY OF THE DISCLOSURE

In the conventional stretchable device, in a case where a wiring is exposed to the outside and a water droplet or a foreign substance is attached across adjacent wirings, a short circuit may occur between the adjacent wirings, and the stretchable device may be damaged. Further, when a metal wiring comes into contact with air or moisture, oxidation or corrosion of the wiring may occur. In view of the above, it is conceivable to cover a surface of a wiring with a protective layer. Specifically, the protective layer is provided only in all portions exposed from the second substrate in the first wiring.

However, it has been found that peeling may occur between the first wiring and the second wiring in a case where, for example, an external force is applied, in a direction orthogonal to an extending direction of the first wiring and parallel to a first main surface of the first substrate, or in a direction orthogonal to the first main surface of the first substrate, to a portion separated from a fulcrum of the first substrate when viewed from a direction orthogonal to the first main surface of the first substrate, the fulcrum being a wiring connection portion that is a connection portion between the first wiring and the second wiring. That is, it has been found that strength of the wiring connection portion is insufficient in the conventional stretchable device.

In view of the above, an object of the present disclosure is to provide a stretchable device in which strength of a wiring connection portion is secured.

In order to solve the above problem, a stretchable device according to one aspect of the present disclosure includes: a first substrate having stretchability; a first wiring on a first main surface of the first substrate; a second substrate that faces the first substrate in a first direction that is a thickness direction of the first substrate and is connected to the first substrate; a second wiring on a first main surface of the second substrate and that faces the first wiring in the first direction; and a first protective layer extending continuously on the first main surface of the first substrate and a second main surface of the second substrate so as to cover at least a part of the first wiring and at least a part of the second substrate, the first wiring and the second wiring are electrically connected in an overlapping region where the first wiring and the second wiring overlap each other when viewed from the first direction, and the first protective layer overlaps an entirety of the overlapping region when viewed from the first direction.

According to the stretchable device of one aspect of the present disclosure, it is possible to suppress reduction in strength of the wiring connection portion.

### BRIEF EXPLANATION OF THE DRAWINGS

FIG. 1 is a partial enlarged top view schematically illustrating a stretchable device according to a first embodiment of the present disclosure.

FIG. 2 is an exploded plan view schematically illustrating the stretchable device according to the first embodiment of the present disclosure.

FIG. 3 is a sectional view taken along III-III of FIG. 1.

FIG. 4 is a partial sectional view of a stretchable device according to a second embodiment of the present disclosure.

FIG. 5 is a partial sectional view of a stretchable device according to a third embodiment of the present disclosure.

FIG. 6 is a partial sectional view of a stretchable device according to a fourth embodiment of the present disclosure.

FIG. 7 is a partial sectional view of a stretchable device according to a fifth embodiment of the present disclosure.

FIG. 8 is a partial sectional view of a stretchable device according to a sixth embodiment of the present disclosure.

FIG. 9 is a partial sectional view of a stretchable device according to a seventh embodiment of the present disclosure.

### MODES FOR CARRYING OUT THE DISCLOSURE

Hereinafter, embodiments of the present disclosure will be described in detail with reference to the drawings. In each embodiment, a difference from description before the embodiment will be mainly described. Particularly, similar functions and effects achieved by similar configurations will not be mentioned sequentially for each of the embodiments. Among constituent elements in the embodiments below, a constituent element not described in an independent claim will be described as an optional constituent element. Further, sizes and size-ratios of constituent elements illustrated in the drawings are not necessarily precise. Further, in the drawings, substantially the same configurations are denoted by the same reference symbols, and redundant description may be omitted or simplified.

### First Embodiment

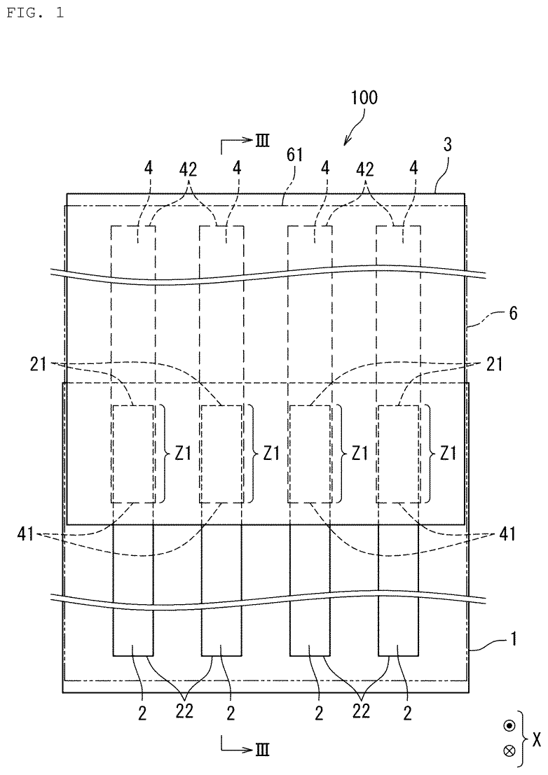

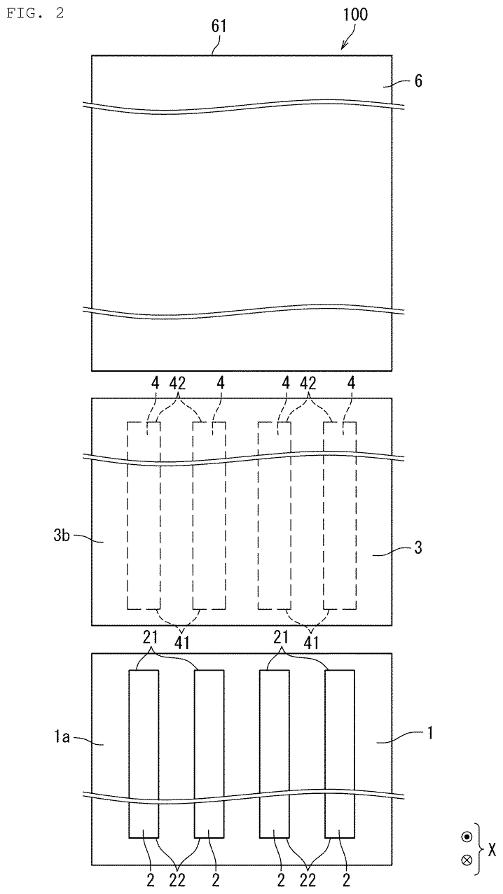

A structure of a stretchable device 100 according to a first embodiment will be described with reference to FIGS. 1, 2, and 3. FIG. 1 is a partial top view of the stretchable device 100. FIG. 2 is an exploded plan view of the stretchable device 100. FIG. 3 is a sectional view of the stretchable device 100 taken along line III-III in FIG. 1. Note that a sectional view in the present description is a sectional view that is parallel to a first direction, which is a thickness direction of a first substrate, and includes an overlapping region (that is, a wiring connection portion) in which a first wiring 2 and a second wiring 4 overlap each other when viewed from the first direction. The first direction is indicated by a double-headed arrow X. A thickness direction of a first substrate 1, a thickness direction of a second substrate 3, and the first direction X coincide with each other. Further, in FIG. 1, for convenience, a first protective layer 6 is indicated by a two-dot chain line, and the first protective layer 6 is drawn to be transparent, but the first protective layer 6 does not need to be transparent.

The stretchable device 100 includes the first substrate 1, the second substrate 3, the first wiring 2, the second wiring 4, and the first protective layer 6. The first substrate 1 and the second substrate 3 are connected. The first wiring 2 provided on a first main surface 1a of the first substrate 1 and the second wiring 4 provided on a first main surface 3a of the second substrate 3 are electrically connected in an overlapping region Z1 overlapping each other when viewed from the first direction X. The first protective layer 6 is provided continuously on the first main surface 1a of the first substrate 1 and a second main surface 3b of the second substrate 3 so as to cover at least a part of the first wiring 2 and at least a part of the second substrate 3.

Note that a shape of the stretchable device 100 is not particularly limited. In the present description, a structure in which two substrates are connected is described as an example, but three or more substrates may be connected. Further, the first wiring 2 is not limited to arrangement as illustrated in FIG. 1, and an extending direction is also not limited. Specifically, a longitudinal direction of the first substrate 1 and an extending direction of the first wiring 2 do not need to coincide with each other, or the first substrate 1 and the first wiring 2 do not need to extend in one direction. Further, the number of the first wirings 2 is not particularly limited, and may be one or more than one. In a case where the number of the first wirings 2 is more than one, the first wirings 2 may include a wiring not electrically connected to the second wiring 4. The same applies to arrangement and the number of the second wirings 4.

Further, the term “on” in the present does not need to coincide with the upper and lower sides when the stretchable device 100 is used. More specifically, “on a main surface of the first substrate 1” refers to not an absolute direction such as a vertical upward direction defined in the direction of gravity, but a direction toward the outside between the outside and the inside with the main surface of the first substrate 1 as a boundary, with the main surface as a reference. The same applies to “on a main surface of the second substrate 3”. Furthermore, “above” with respect to a certain element includes not only an upper position away from the element, that is, an upper position with another object interposed between them on the element or an upper position at an interval, but also a position in contact with and immediately above (on) the element.

Hereinafter, these constituent elements and arrangement of these will be described. As illustrated in FIGS. 1, 2, and 3, the first substrate 1 and the second substrate 3 face each other in the first direction X, and a part of the first substrate 1 and a part of the second substrate 3 overlap each other as viewed from the first direction X. Similarly, the first wiring 2 and the second wiring 4 face each other in the first direction X.

The first substrate 1 has stretchability. Since the first substrate 1 has stretchability, it is possible to reduce the risk of breakage due to expansion and contraction at the time of use of the stretchable device 100 without suppressing expansion and contraction of the first wiring 2.

Examples of stretchable substrates include a sheet-shaped or film-shaped substrate made from a stretchable resin material. The resin material preferably contains, for example, at least one type of resin selected from a group including acryl-based resin, styrene-based resin, and urethane-based resin. Examples of the urethane-based resin include thermoplastic polyurethane. Thickness of the first substrate 1 is not particularly limited, but is preferably 1 mm or less, more preferably 100 μm or less, still more preferably 50 μm or less from the viewpoint of preventing impairment of expansion and contraction of a surface of a living body when the first substrate 1 is attached to the living body. Further, thickness of the first substrate 1 is more preferably 1 μm or more. The first substrate 1 has the first main surface 1a and a second main surface 1b located on the opposite side to each other.

The first wiring 2 is provided on the first main surface 1a of the first substrate 1. The first wiring 2 preferably has stretchability. Examples of a material of the first wiring 2 include a mixture of metal powder of Ag, Cu, Ni, or the like as conductive particles and elastomer-based resin such as silicone resin. An average particle size of the conductive particles is not particularly limited, but is preferably 0.01 μm to 10 μm. Further, a shape of the conductive particles is preferably spherical, and is not limited to spherical, and may be a flat shape for improving stretchability or a structure having a protrusion. Further, the elastomer-based resin contains at least one type of resin (elastomer-based resin) selected from a group including epoxy-based resin, urethane-based resin, acryl-based resin, and silicone-based resin, and is preferable in securing stretchability.

The first wiring 2 has a first end portion 21 and a second end portion 22. The first end portion 21 is an end portion on the overlapping region Z1 side between both end portions in an extending direction. In other words, the first end portion 21 is an end portion overlapping the second wiring 4 when viewed from the first direction X. The second end portion 22 is an end portion on the opposite side to the first end portion 21 with respect to the center in the extending direction of the first wiring 2.

Thickness of the first wiring 2 is preferably 100 μm or less, more preferably 50 μm or less. Further, thickness of a stretchable wiring is more preferably 1 μm or more. Further, thickness, width, and length of the first wiring 2 are not particularly limited. Note that the first wiring 2 does not need to have stretchability.

A method of forming the first wiring 2 on the first substrate 1 will be described. In a case where a material of the first wiring 2 is, for example, conductive paste containing a mixture of Ag and resin, the conductive paste is applied to the first substrate 1. The method of application may be screen printing, gravure printing or inkjet printing. After the above, the conductive paste is thermally cured so as to obtain a predetermined resistance value, and in this manner, the first wiring 2 is formed on the first substrate 1.

The second substrate 3 preferably has stretchability. The second substrate 3 has Young's modulus larger than that of the first wiring 2. Specifically, a substrate, such as a flexible printed circuit (FPC), a flexible flat cable (FFC), a printed circuit board (PCB), or the like, is used. By making the Young's modulus larger than that of the first wiring 2, pressure is easily applied to a bonding portion at the time of pressure bonding, and bonding can be performed with low pressure. That is, by using low pressure, damage to a substrate at the time of bonding can be reduced. Further, the second substrate 3 preferably has Young's modulus larger than that of the first substrate 1. Since it is resistant to an impact at the time of connection, connection reliability can be further improved. The second substrate 3 has the first main surface 3a and the second main surface 3b located on the opposite side to each other.

The second substrate 3 is connected to the first substrate 1. That is, the first main surface 1a of the first substrate 1 and the first main surface 3a of the second substrate 3 are directly connected by welding or the like.

Specifically, the first main surface 1a of the first substrate 1 and the first main surface 3a of the second substrate 3 are thermal compression-bonded. Note that the first substrate 1 and the second substrate 3 may be connected by an adhesive member such as a thermoplastic adhesive.

Note that the second substrate 3 does not need to have stretchability. Examples of the second substrate 3 include sheet-like or film-like substrates of polyethylene terephthalate (PET), polyimide, and the like, and substrates such as FPC, FFC, and PCB. Further, the second substrate 3 may be the same as the first substrate 1.

The second wiring 4 is provided on the first main surface 3a of the second substrate 3. The second wiring 4 preferably has stretchability. The second wiring 4 is preferably a wiring having Young's modulus larger than that of the first wiring 2. For example, a metal wiring of copper foil or the like is used. Thickness of the second wiring 4 is preferably 1 μm to 100 μm, and more preferably 50 μm or less. In this embodiment, the first wiring 2 and the second wiring 4 are in direct contact and electrically connected in the overlapping region Z1. The overlapping region Z1 is a region where the first wiring 2 and the second wiring 4 overlap each other when viewed from the first direction X, and is a region where the first wiring 2 and the second wiring 4 may be electrically connected. Although the first wiring 2 and the second wiring 4 are in direct contact in the entire region of the overlapping region Z1, the present disclosure is not limited to this, and the first wiring 2 and the second wiring 4 may be in direct contact in a part of the overlapping region Z1. Note that the second wiring 4 does not need to have stretchability. Further, the second wiring 4 may be the same as the first wiring 2.

The second wiring 4 has a first end portion 41 and a second end portion 42. The first end portion 41 is an end portion on the overlapping region Z1 side between both end portions in an extending direction. In other words, the first end portion 41 is an end portion overlapping the first wiring 2 when viewed from the first direction X. The second end portion 42 is an end portion on the opposite side to the overlapping region Z1 (first end portion 41) with respect to the center in the extending direction of the second wiring 4.

The second wiring 4 is electrically connected to the first wiring 2. Specifically, the first wiring 2 and the second wiring 4 are electrically connected in contact with each other. Note that the first wiring 2 and the second wiring 4 may be electrically connected by a conductive connection member.

The first protective layer 6 is provided continuously on the first main surface 1a of the first substrate 1 and a second main surface 3b of the second substrate 3 so as to cover at least a part of the first wiring 2 and at least a part of the second substrate 3. The first protective layer 6 overlaps the entire overlapping region Z1 when viewed from the first direction X. In other words, the first protective layer 6 covers the entire overlapping region Z1. Since the first protective layer 6 covers at least a part of the first wiring 2, it is possible to suppress a short circuit between the first wirings 2 adjacent to each other when a water droplet or a foreign substance is attached across the first wirings 2 adjacent to each other, and it is possible to reduce contact of the first wiring 2 with air or moisture and to more reliably suppress occurrence of oxidation or corrosion of the first wirings 2.

Specifically, the first protective layer 6 covers the entire outer surface of a portion other than the overlapping region Z1 of the first wiring 2. More specifically, the first protective layer 6 is in contact with the entire outer surface of a portion other than the overlapping region Z1 of the first wiring 2 (hereinafter, a portion of the first protective layer 6 in contact with the entire outer surface is referred to as “first portion”). In other words, the first protective layer 6 is in contact with the entire surface of a portion of an outer surface of the first wiring 2 exposed from the first substrate 1, the second substrate 3, and the second wiring 4. Note that the first protective layer 6 may cover a part of an outer surface of a portion other than the overlapping region Z1 of the first wiring 2. For example, the first protective layer 6 may cover the first wiring 2 such that the second end portion 22 of the first wiring 2 is exposed.

Further, the first protective layer 6 covers at least an end portion on the overlapping region Z1 side of the second main surface 3b of the second substrate 3. More specifically, the first protective layer 6 is in contact with at least an end portion on the overlapping region Z1 side of the second main surface 3b of the second substrate 3 (hereinafter, a portion of the first protective layer 6 in contact with an end portion on the overlapping region Z1 side is referred to as “second portion”). The end portion overlaps the entire overlapping region Z1 when viewed from the first direction X. By the above, the first protective layer 6 overlaps the entire overlapping region Z1 when viewed from the first direction X.

Further, the first protective layer 6 covers a side surface on the overlapping region Z1 side of the second substrate 3 and a side surface (first end portion 41) on the overlapping region Z1 side of the second wiring 4 (hereinafter, this covered portion of the first protective layer 6 is referred to as “third portion”). More specifically, the first protective layer 6 is in contact with a side surface on the overlapping region Z1 side of the second substrate 3, and has a gap with a side surface (first end portion 41) on the overlapping region Z1 side of the second wiring 4. Note that the first protective layer 6 may be in contact with the first end portion 41 of the second wiring 4.

The first portion, the third portion, and the second portion are continuous in this order. In short, the first protective layer 6 covers the entire first wiring 2 including the overlapping region Z1 and covers at least a part of the second wiring 4. By the above, the first protective layer 6 also covers the entire overlapping region Z1 in addition to a portion exposed from the first substrate 1, the second substrate 3, and the second wiring 4 of an outer surface of the first wiring 2.

Specifically, the first protective layer 6 is preferably a resin material or a mixture of a resin material and an inorganic material as an example, and examples of the resin material include elastomer-based resin such as urethane-based, styrene-based, olefin-based, silicone-based, fluorine-based, nitrile rubber, latex rubber, vinyl chloride, ester-based, and amide-based resin, epoxy, phenol, acrylic, polyester, imide-based, rosin, cellulose, polyethylene terephthalate-based, polyethylene naphthalate-based, and polycarbonate-based resin. Further, the first protective layer 6 preferably has insulating property. Since the first protective layer 6 has insulating property, ion migration in the first wiring 2 can be more reliably suppressed. The first protective layer 6 is provided by, for example, applying an insulating material or bonding a laminate material.

Thickness of the first protective layer 6 is preferably 1 μm to 100 μm, and more preferably 50 μm or less. By setting thickness of the first protective layer 6 to 1 μm or more, durability of the first protective layer 6 can be secured. Further, by setting thickness of the first protective layer 6 to 100 μm or less, overall height can be reduced. Note that in a case where thickness of the first protective layer 6 is not constant, a maximum dimension in the first direction X of the first protective layer 6 is defined as the thickness.

Further, the first protective layer 6 has a first protective layer end portion 61. The first protective layer end portion 61 is an end portion overlapping the second substrate 3 when viewed from the first direction X. Specifically, the first protective layer end portion 61 is an end portion overlapping the second substrate 3 between both end portions in a vertical direction in FIG. 1, and is an end portion overlapping the second substrate 3 between both end portions in a horizontal direction in FIG. 3.

According to the stretchable device 100, the first protective layer 6 overlaps the entire overlapping region Z1 when viewed from the first direction X. For this reason, in the overlapping region Z1, stretching performance of the first substrate 1 can be reduced as compared with the conventional technique in which no protective layer is provided, and rigidity of the stretchable device 100 can be increased. As a result, peeling between the first wiring 2 and the second wiring 4 can be suppressed and strength of the overlapping region Z1 can be secured also in a case where, for example, external force acts, in a direction orthogonal to an extending direction of the first wiring 2 and parallel to the first main surface 1a of the first substrate 1 (horizontal direction in FIG. 1) or in a direction orthogonal to the first main surface 1a of the first substrate 1, on a portion separated from a fulcrum of the first substrate 1 when viewed from a direction (the first direction X) orthogonal to the first main surface 1a of the first substrate 1, the fulcrum being the overlapping region Z1 (that is, a wiring connection portion).

On the other hand, in the conventional technique in which the first protective layer covers only an exposed portion of the first wiring and does not cover an overlapping region between the first wiring and the second wiring, there is a possibility that peeling occurs between the first wiring and the second wiring in a case where external force acts in the above-described direction on a portion separated from the overlapping region as a fulcrum of the first substrate. Further, in a case where the first protective layer 6 covers only a part of the overlapping region Z1 when viewed from the first direction X, there is a possibility that peeling occurs between the first wiring 2 and the second wiring 4 in a case where external force acts in the above-described direction on a portion separated from a fulcrum of the first substrate 1, the fulcrum being the overlapping region Z1, and there is a possibility that strength of the overlapping region Z1 becomes insufficient.

Further, according to the stretchable device 100, since rigidity of the stretchable device 100 can be made high in the overlapping region Z1, for example, also in a case where the second substrate 3 is pulled in an extending direction of the second wiring 4, cracking of the second substrate 3 can be suppressed.

Preferably, as illustrated in FIG. 1, the first protective layer 6 covers the entire first wiring 2. In other words, the first protective layer 6 overlaps the entire first wiring 2 when viewed from the first direction X. According to this configuration, it is possible to more reliably suppress a short circuit between the first wirings 2 adjacent to each other when a water droplet or a foreign substance is attached across the first wirings 2 adjacent to each other, and it is possible to more reliably reduce contact of the first wiring 2 with air or moisture and to more reliably suppress occurrence of oxidation or corrosion of the first wirings 2.

Preferably, as illustrated in FIG. 3, the second wiring 4 has a first non-overlapping region 22 that does not overlap with the first wiring 2 when viewed from the first direction X. The first protective layer 6 overlaps the entire first non-overlapping region Z2 when viewed from the first direction X. When viewed from the first direction X, a portion P1 of the first protective layer 6 overlapping the first non-overlapping region Z2 and a portion P2 of the first protective layer 6 overlapping the overlapping region Z1 are continuous. According to this configuration, since the first protective layer 6 overlaps the entire first non-overlapping region Z2 in addition to the entire overlapping region Z1 when viewed from the first direction X, strength of the overlapping region Z1 can be more sufficiently secured than a case where the first protective layer 6 does not overlap the first non-overlapping region Z2. The first non-overlapping region Z2 corresponds to an example of “non-overlapping region” described in the claims.

Next, connection of the stretchable device 100 will be described. In a case where the first substrate 1 and the second substrate 3 are connected, the first substrate 1 and the second substrate 3 are thermal compression-bonded by heating and pressurizing. By the above, the first substrate 1 and the second substrate 3 are connected. Note that a pressure bonding method of the first substrate 1 and the second substrate 3 is not particularly limited. Further, the first wiring 2 and the second wiring 4 are in contact with and electrically connected to each other.

### Second Embodiment

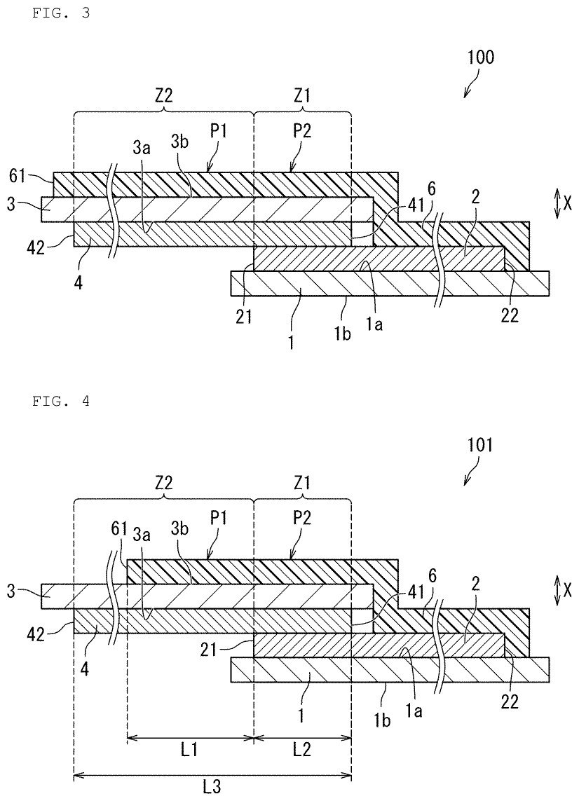

Next, a second embodiment will be described with reference to FIG. 4. FIG. 4 is a partial sectional view of a stretchable device 101 according to the second embodiment. The stretchable device 101 according to the second embodiment is different from the stretchable device 100 according to the first embodiment in that size of the first protective layer 6 is different.

As illustrated in FIG. 4, in the stretchable device 101 of the second embodiment, the second wiring 4 has a first non-overlapping region Z2 that does not overlap with the first wiring 2 when viewed from the first direction X. The first protective layer 6 overlaps a part of the first non-overlapping region Z2 when viewed from the first direction X. When viewed from the first direction X, a portion P1 of the first protective layer 6 overlapping the first non-overlapping region Z2 and a portion P2 of the first protective layer 6 overlapping the overlapping region Z1 are continuous.

Specifically, unlike the first embodiment, the first protective layer 6 covers not the entire second wiring 4 but a part of the second wiring 4 including the overlapping region Z1. In other words, the first protective layer end portion 61 is located between the first end portion 21 of the first wiring 2 and the second end portion 42 of the second wiring 4 when viewed from the first direction X. In other words, furthermore, the second substrate 3 has a region covered with the first protective layer 6 and a region exposed from the first protective layer 6.

According to the above configuration, it is possible to form gradation of hardness in the stretchable device 101. Specifically, as illustrated in FIG. 4, in the stretchable device 101, five layers of the first substrate 1, the first wiring 2, the second wiring 4, the second substrate 3, and the first protective layer 6 are laminated at a position corresponding to the portion P2 of the first protective layer 6, that is, between the first end portion 41 of the second wiring 4 and the first end portion 21 of the first wiring 2. In the stretchable device 101, three layers of the second wiring 4, the second substrate 3, and the first protective layer 6 are laminated at a position corresponding to the portion P1 of the first protective layer 6, that is, between the first end portion 21 of the first wiring 2 and the first protective layer end portion 61. Furthermore, in the stretchable device 101, two layers of the second wiring 4 and the second substrate 3 are laminated between the first protective layer end portion 61 and the second end portion 42 of the second wiring 4. That is, the number of layered members decreases from the first end portion 41 toward the second end portion 42 of the second wiring 4, and hardness of the stretchable device 101 can be reduced in stages. By the above, also in a case where external force is applied to the stretchable device 101, stress that may be generated in the second substrate 3 can be dispersed. As a result, damage to the second substrate 3 can be suppressed.

Length L1 of the portion P1 of the first protective layer 6 in an extending direction of the second wiring 4 is preferably 50% or more, more preferably 100% or more of length L2 of the portion P2 of the first protective layer 6 in the extending direction of the second wiring 4. According to this configuration, gradation of hardness can be easily formed in the stretchable device 101, and breakage of the second substrate 3 can be more reliably suppressed.

The length L1 of the portion P1 of the first protective layer 6 in the extending direction of the second wiring 4 is preferably 70% or less, more preferably 30% or less of a value obtained by subtracting the length L2 from length L3 in the extending direction of the second wiring 4. According to this configuration, gradation of hardness can be easily formed in the stretchable device 101, and breakage of the second substrate 3 can be more reliably suppressed.

### Third Embodiment

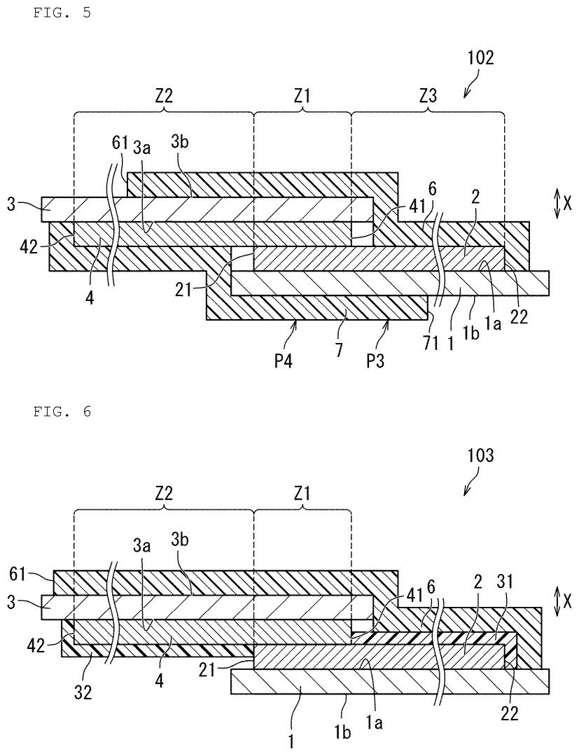

Next, a third embodiment will be described with reference to FIG. 5. FIG. 5 is a partial sectional view of a stretchable device 102 according to the third embodiment. The stretchable device 102 according to the third embodiment is different from the stretchable device 100 according to the first embodiment in that a second protective layer is provided.

As illustrated in FIG. 5, the stretchable device 102 of the third embodiment further includes a second protective layer 7. A material and thickness of the second protective layer 7 are preferably the same as a material and thickness of the first protective layer 6.

The second protective layer 7 is provided continuously on the first main surface 3a of the second substrate 3 and the second main surface 1b of the first substrate 1 so as to cover at least a part of the second wiring 4 and at least a part of the first substrate 1.

Specifically, the second protective layer 7 covers the entire outer surface of a portion other than the overlapping region Z1 of the second wiring 4. More specifically, the second protective layer 7 is in contact with the entire outer surface of a portion other than the overlapping region Z1 of the second wiring 4 (hereinafter, a portion of the second protective layer 7 in contact with the entire outer surface is referred to as “fourth portion”). In other words, the second protective layer 7 is in contact with the entire surface of a portion exposed from the first substrate 1, the second substrate 3, and the first wiring 2 of an outer surface of the second wiring 4. Note that the second protective layer 7 may cover a part of an outer surface of a portion other than the overlapping region Z1 of the second wiring 4. For example, the second protective layer 7 may cover the second wiring 4 such that the second end portion 42 of the second wiring 4 is exposed.

Further, the second protective layer 7 covers at least an end portion on the overlapping region Z1 side of the second main surface 1b of the first substrate 1. More specifically, the second protective layer 7 is in contact with at least an end portion on the overlapping region Z1 side of the second main surface 1b of the first substrate 1 (hereinafter, a portion of the second protective layer 7 in contact with an end portion on the overlapping region Z1 side is referred to as “fifth portion”). In the present embodiment, the end portion overlaps the entire overlapping region Z1 when viewed from the first direction X. By the above, the second protective layer 7 overlaps the entire overlapping region Z1 when viewed from the first direction X. Note that the second protective layer 7 may overlap a part of the overlapping region Z1 when viewed from the first direction X.

Further, the second protective layer 7 covers a side surface on the overlapping region Z1 side of the first substrate 1 and a side surface (first end portion 21) on the overlapping region Z1 side of the first wiring 2 (hereinafter, this covered portion of the second protective layer 7 is referred to as “sixth portion”). More specifically, the second protective layer 7 is in contact with a side surface on the overlapping region Z1 side of the first substrate 1, and has a gap with a side surface (first end portion 21) on the overlapping region Z1 side of the first wiring 2. Note that the second protective layer 7 may be in contact with the first end portion 21 of the first wiring 2.

The fourth portion, the sixth portion, and the fifth portion are continuous in this order. In short, the second protective layer 7 covers the entire second wiring 4 including the overlapping region Z1 and covers at least a part of the first wiring 2. By the above, the second protective layer 7 also covers the entire overlapping region Z1 in addition to a portion exposed from the first substrate 1, the second substrate 3, and the first wiring 2 of an outer surface of the second wiring 4.

Further, the second protective layer 7 has a second protective layer end portion 71. The second protective layer end portion 71 is an end portion overlapping the first substrate 1 when viewed from the first direction X. Specifically, the second protective layer end portion 71 is an end portion overlapping the first substrate 1 between both end portions in the horizontal direction in FIG. 5.

According to the above configuration, since the second protective layer 7 covers at least a part of the second wiring 4, it is possible to suppress a short circuit between the second wirings 4 adjacent to each other when a water droplet or a foreign substance is attached across the second wirings 4 adjacent to each other, and it is possible to reduce contact of the second wiring 4 with air or moisture and to suppress occurrence of oxidation or corrosion of the second wiring 4.

Preferably, as illustrated in FIG. 5, the first wiring 2 has a second non-overlapping region Z3 that does not overlap the second wiring 4 when viewed from the first direction X. The second protective layer 7 overlaps a part of the second non-overlapping region Z3 when viewed from the first direction X. When viewed from the first direction X, a portion P3 of the second protective layer 7 overlapping the second non-overlapping region Z3 and a portion P4 of the second protective layer 7 overlapping the overlapping region Z1 are continuous.

Specifically, the second protective layer 7 covers a part of the first wiring 2 including the overlapping region Z1. In other words, the second protective layer end portion 71 is located between the second end portion 22 of the first wiring 2 and the first end portion 41 of the second wiring 4 when viewed from the first direction X.

According to the above configuration, similarly to the second embodiment, gradation of hardness of the stretchable device 102 can be formed also on the side where the first wiring 2 is provided. That is, the number of layered members decreases from the first end portion 21 toward the second end portion 22 of the first wiring 2, and hardness of the stretchable device 102 can be reduced in stages. By the above, also in a case where external force is applied to the stretchable device 102, stress that may be generated in the first substrate 1 can be dispersed. As a result, damage to the first substrate 1 can be suppressed.

Note that the second protective layer 7 may cover the entire second main surface 1b of the first substrate 1. By the above, entry of moisture from the second main surface 1b side of the first substrate 1 can be more reliably suppressed.

### Fourth Embodiment

Next, a fourth embodiment will be described with reference to FIG. 6. FIG. 6 is a partial sectional view of a stretchable device 103 according to the fourth embodiment. The stretchable device 103 according to the fourth embodiment is different from the stretchable device 100 according to the first embodiment in that a first insulating layer and a second insulating layer are provided.

As illustrated in FIG. 6, the stretchable device 103 of the fourth embodiment further includes a first insulating layer 31 and a second insulating layer 32. A material of the first insulating layer 31 and the second insulating layer 32 are different from a material of the first protective layer 6.

As the first insulating layer 31 and the second insulating layer 32, those having a water absorption rate lower than that of the first substrate 1 are preferable. Examples of a material of the first insulating layer 31 and the second insulating layer 32 include silicone-based resin, acryl-based resin, olefin-based resin, modified urethane-based resin, vinyl chloride-based resin, and polyester-based, polyamide-based, polyolefin-based, polyethylene-based, and polypropylene-based resin materials. The first insulating layer 31 and the second insulating layer 32 are formed by, for example, printing.

The first insulating layer 31 covers at least a part of an exposed surface of the first wiring 2. The exposed surface of the first wiring 2 is a surface exposed from the first substrate 1 and the second wiring 4 in an outer surface of the first wiring 2. Specifically, the exposed surface of the first wiring 2 is a surface that is not covered with the first substrate 1 or the second wiring 4 in the first wiring 2. The first insulating layer 31 preferably covers the entire exposed surface of the first wiring 2, but may cover a part of the exposed surface of the first wiring 2. Further, the first insulating layer 31 is preferably present between the first wiring 2 and the first protective layer 6. Further, although the first insulating layer 31 does not overlap the second wiring 4 in the first direction X, a part of the first insulating layer 31 may overlap the second wiring 4 in the first direction X. According to the above configuration, the first insulating layer 31 prevents a short circuit between the first wirings 2 adjacent to each other due to a water droplet or a foreign matter, and reliability is improved.

Here, a method of forming the first insulating layer 31 will be described, and insulating paste as a material of the first insulating layer 31 is printed on the first wiring 2 using a screen printing method or the like. At this time, in a cross section orthogonal to an extending direction of the first wiring 2, insulating paste is preferably printed larger than width of the first wiring 2 by 1 μm to 10 mm, and more preferably printed larger than width of the first wiring 2 by 20 μm to 1000 μm.

The second insulating layer 32 covers at least a part of an exposed surface of the second wiring 4. The exposed surface of the second wiring 4 is a surface exposed from the second substrate 3 and the first wiring 2 in an outer surface of the second wiring 4. Specifically, the exposed surface of the second wiring 4 is a surface that is not covered with the second substrate 3 or the first wiring 2 in the second wiring 4. The second insulating layer 32 preferably covers the entire exposed surface of the second wiring 4, but may cover a part of the exposed surface of the second wiring 4. Further, although the second insulating layer 32 does not overlap the first wiring 2 in the first direction X, a part of the second insulating layer 32 may overlap the first wiring 2 in the first direction X.

According to the above configuration, the second insulating layer 32 prevents a short circuit between the second wirings 4 adjacent to each other due to a water droplet or a foreign matter, and reliability is improved.

Note that the configuration may be such that only one of the first insulating layer 31 and the second insulating layer 32 is provided. In addition, at least one of the first insulating layer 31 and the second insulating layer 32 may be provided in the stretchable devices 101 and 102 according to the second and third embodiments.

### Fifth Embodiment

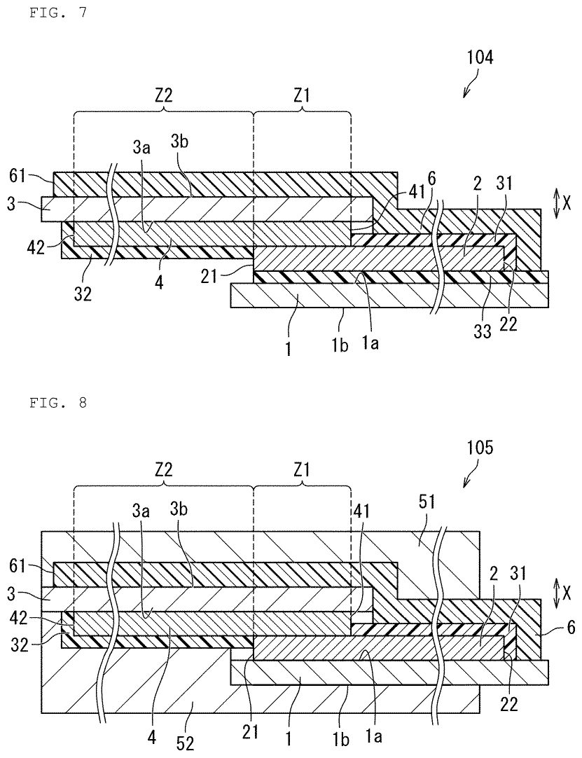

Next, a fifth embodiment will be described with reference to FIG. 7. FIG. 7 is a partial sectional view of a stretchable device 104 according to the fifth embodiment. The stretchable device 104 according to the fifth embodiment is different from the stretchable device 103 according to the fourth embodiment in that a third insulating layer is provided.

As illustrated in FIG. 7, the stretchable device 104 of the fifth embodiment further includes a third insulating layer 33. A material of the third insulating layer 33 is preferably the same as a material of the first insulating layer 31 and the second insulating layer 32.

The third insulating layer 33 is arranged between the first wiring 2 and the first substrate 1 in the first direction X. In other words, the third insulating layer 33 is provided on the first main surface 1a of the first substrate 1 and is in contact with a lower surface of the first wiring 2.

In a case where the first substrate 1 has moisture permeability, moisture may enter the first wiring 2 from the first substrate 1, and ion migration may occur. By providing the third insulating layer 33, entry of moisture from the first substrate 1 to the first wiring 2 can be suppressed. That is, the stretchable device 104 in which a short circuit of the first wiring 2 is suppressed is provided.

Note that the stretchable devices 100, 101, and 102 according to the first, second, and third embodiments may be provided with the third insulating layer 33.

Further, for example, the third insulating layer 33 may be arranged so as to cover only a lower surface of the first wiring 2, or may be arranged at a portion where the first wiring 2 of the first substrate 1 is not present. Further, the third insulating layer 33 may be arranged so as to cover the entire first substrate 1. Further, the third insulating layer 33 only needs to be in contact with the first wiring 2, and a different layer may be arranged between the first substrate 1 and the third insulating layer 33.

### Sixth Embodiment

Next, a sixth embodiment will be described with reference to FIG. 8. FIG. 8 is a partial sectional view of a stretchable device 105 according to the sixth embodiment. The stretchable device 105 according to the sixth embodiment is different from the stretchable device 103 according to the fourth embodiment in that a first coating layer and a second coating layer are provided.

As illustrated in FIG. 8, the stretchable device 105 of the sixth embodiment further includes a first coating layer 51 and a second coating layer 52. A material of the first coating layer 51 and the second coating layer 52 is different from a material of the first protective layer 6.

The first coating layer 51 covers at least an end portion on the first substrate side of the second substrate 3. With the structure as described above, the second substrate 3 can be protected from external force. More preferably, the first coating layer 51 covers the first main surface 1a side of the first substrate 1. Specifically, the first coating layer 51 covers at least a part of the second main surface 3b of the second substrate 3, at least a part of the first insulating layer 31, at least a part of the first protective layer 6, and at least a part of the second main surface 3b of the second substrate 3. With the above configuration, the first wiring 2 and the first protective layer 6 can be protected from external force.

Examples of the first coating layer 51 include a resin material. For example, the first coating layer 51 is preferably resin having flexibility. Specifically, the first coating layer 51 is formed of ionomer-based resin, polyester-based resin, styrene-based resin, olefin-based resin, epoxy-based resin, urethane-based resin, acryl-based resin, or silicone-based resin, and is preferably formed of silicone-based resin. Note that the first coating layer 51 may be thermoplastic resin. Note that the first coating layer 51 may be formed of a plurality of members. By using resin for the first coating layer 51, a connection portion can be further protected from external force.

The second coating layer 52 covers at least an end portion on the first substrate side of the second substrate 3. With the structure as described above, the second substrate 3 can be protected from external force. More preferably, the second coating layer 52 covers the first main surface 3a side of the second substrate 3. Specifically, the second coating layer 52 covers at least a part of the second main surface 1b of the first substrate 1, at least a part of the second insulating layer 32, and at least a part of the first main surface 3a of the second substrate 3. With the above configuration, the second wiring 4 and the first protective layer 6 can be protected from external force.

Examples of the second coating layer 52 include a resin material. For example, the second coating layer 52 is preferably resin having flexibility. Specifically, the second coating layer 52 is formed of ionomer-based resin, polyester-based resin, styrene-based resin, olefin-based resin, epoxy-based resin, urethane-based resin, acryl-based resin, or silicone-based resin, and is preferably formed of silicone-based resin. Note that the second coating layer 52 may be thermoplastic resin. Note that the second coating layer 52 may be formed of a plurality of members. Further, the first coating layer 51 and the second coating layer 52 may be the same member or different members.

A resin-containing member such as the first protective layer 6, the first insulating layer 31, and the second insulating layer 32 may have cytotoxicity. By providing the first coating layer 51, leakage of a component having cytotoxicity can be suppressed. The same applies to an effect of the second coating layer 52. Further, by providing the first coating layer 51 and the second coating layer 52, it is possible to suppress leakage of a component having higher cytotoxicity.

Note that the configuration may be such that only one of the first coating layer 51 and the second coating layer 52 is provided. Further, at least one of the first coating layer 51 and the second coating layer 52 may be provided in the stretchable devices 100, 101, 102, and 104 according to the first, second, third, and fifth embodiments.

### Seventh Embodiment

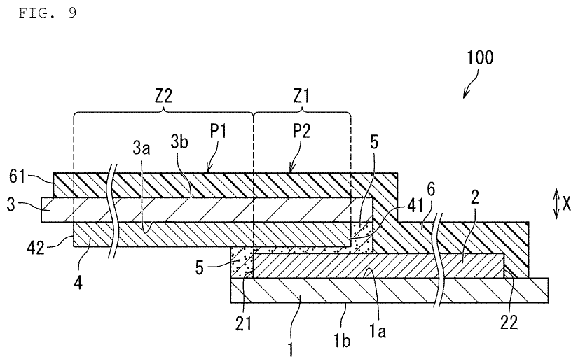

Next, a seventh embodiment will be described with reference to FIG. 9. FIG. 9 is a partial sectional view of a stretchable device 106 according to the seventh embodiment. The stretchable device 106 according to the seventh embodiment is different from the stretchable device 100 according to the first embodiment in that a connection member is provided.

As illustrated in FIG. 9, the stretchable device 106 of the seventh embodiment further includes a connection member 5. In FIG. 9, the connection member 5 is indicated by dot hatching for convenience. The connection member 5 electrically connects the first wiring 2 and the second wiring 4.

A part of the connection member 5 is located between the first wiring 2 and the second wiring 4. Further, a part of the connection member 5 is located outside the first end portion 21 of the first wiring 2 so as to cover the first end portion 21 of the first wiring 2. Further, a part of the connection member 5 is located between the first end portion 41 of the second wiring 4 and the first protective layer 6 so as to cover the first end portion 41 of the second wiring 4. Examples of the connection member 5 include an anisotropic conductive film (ACF), conductive paste, and solder. The connection member 5 preferably contains resin and conductive particles. When the conductive particles contained in the connection member 5 come into contact with the first wiring 2 and the second wiring 4, the first wiring 2 and the second wiring 4 are electrically connected.

Furthermore, the connection member 5 connects the first wiring 2 and the second wiring 4. Further, the connection member 5 is in contact with the first main surface 1a of the first substrate 1 and the first main surface 3a of the second substrate 3 to connect the first substrate 1 and the second substrate 3.

Next, connection of the stretchable device 106 will be described. In a case where the first substrate 1 and the second substrate 3 are to be connected, the first substrate 1 and the second substrate 3 may be subjected to pressure bonding such as pressurization. By performing such processing, the connection member 5 is deformed, and the entire thickness changes. That is, reduction in height of the stretchable device 106 can be achieved. Further, as described above, in a case where the connection member 5 contains conductive particles and the connection member 5 is provided between the first wiring 2 and the second wiring 4, conduction cannot be achieved when a distance between the first wiring 2 and the second wiring 4 in the first direction X is larger than a maximum diameter of the conductive particles. In such a case, the distance between the first wiring 2 and the second wiring 4 in the first direction X is reduced by performing the above-described pressure bonding. Therefore, the first wiring 2 and the second wiring 4 can be electrically connected more reliably.

Note that in a case where the first wiring 2 and the second wiring 4 are electrically connected before pressure bonding, pressure bonding does not need to be performed. Further, in a case where the connection member 5 has adhesiveness, pressure bonding does not need to be performed. Further, a pressure bonding method is not particularly limited.

Note that the present disclosure is not limited to the above-described embodiment, and can be changed in design without departing from the gist of the present disclosure. For example, features of the first to seventh embodiments may be combined in various manners.

The present disclosure includes an aspect below.

<1> A stretchable device including: a first substrate having stretchability; a first wiring on a first main surface of the first substrate; a second substrate that faces the first substrate in a first direction that is a thickness direction of the first substrate and is connected to the first substrate; a second wiring on a first main surface of the second substrate and that faces the first wiring in the first direction; and a first protective layer extending continuously on the first main surface of the first substrate and a second main surface of the second substrate so as to cover at least a part of the first wiring and at least a part of the second substrate, in which the first wiring and the second wiring are electrically connected in an overlapping region where the first wiring and the second wiring overlap each other when viewed from the first direction, and the first protective layer overlaps an entirety of the overlapping region when viewed from the first direction.

<2> The stretchable device according to <1>, in which the first protective layer covers an entirety of the first wiring.

<3> The stretchable device according to <1> or <2>, in which the second wiring has a non-overlapping region that does not overlap the first wiring when viewed from the first direction, the first protective layer overlaps an entirety of the non-overlapping region when viewed from the first direction, and a first portion of the first protective layer overlapping the non-overlapping region and a second portion of the first protective layer overlapping the overlapping region are continuous when viewed from the first direction.

<4> The stretchable device according to <1> or <2>, in which the second wiring has a non-overlapping region that does not overlap the first wiring when viewed from the first direction, the first protective layer overlaps a part of the non-overlapping region when viewed from the first direction, and a first portion of the first protective layer overlapping the non-overlapping region and a second portion of the first protective layer overlapping the overlapping region are continuous when viewed from the first direction.

<5> The stretchable device according to <4>, in which when viewed from the first direction, a first protective layer end portion of the first protective layer is between a first end portion on an overlapping region side in an extending direction of the first wiring and a second end portion on a side opposite to the overlapping region in an extending direction of the second wiring.

<6> The stretchable device according to any one of <1> to <5>, further including a second protective layer extending continuously on the first main surface of the second substrate and a second main surface of the first substrate so as to cover at least a part of the second wiring and at least a part of the first substrate.

<7> The stretchable device according to any one of <1> to <6>, further including a first insulating layer that covers at least a part of an exposed surface of the first wiring.

<8> The stretchable device according to any one of <1> to <7>, further including a second insulating layer that covers at least a part of an exposed surface of the second wiring.

<9> The stretchable device according to any one of <1> to <8>, further including a third insulating layer between the first wiring and the first substrate.

<10> The stretchable device according to any one of <1> to <9>, further including a first coating layer that covers a first main surface side of the first substrate.

<11> The stretchable device according to any one of <1> to <10>, further including a second coating layer that covers a first main surface side of the second substrate.

### DESCRIPTION OF REFERENCE SYMBOLS

100, 101, 102, 103, 104, 105, 106: Stretchable device
1: First substrate
1a: First main surface
1b: Second main surface
2: First wiring
21: First end portion
22: Second end portion
3: Second substrate
3a: First main surface
3b: Second main surface
4: Second wiring
41: First end portion
42: Second end portion
5: Connection member
6: First protective layer
61: First protective layer end portion
7: Second protective layer
71: Second protective layer end portion
31: First insulating layer
32: Second insulating layer
33: Third insulating layer
51: First coating layer
52: Second coating layer
L1, L2, L3: Length
P1: Portion of first protective layer overlapping first non-overlapping region
P2: Portion of first protective layer overlapping region
P3: Portion of second protective layer overlapping second non-overlapping region
P4: Portion of second protective layer overlapping region
X: First direction
Z1: Overlapping region
Z2: First non-overlapping region
Z3: Second non-overlapping region

1. A stretchable device comprising:
a first substrate having stretchability;
a first wiring on a first main surface of the first substrate;
a second substrate that faces the first substrate in a first direction that is a thickness direction of the first substrate and is connected to the first substrate;
a second wiring on a first main surface of the second substrate and that faces the first wiring in the first direction; and
a first protective layer extending continuously on the first main surface of the first substrate and a second main surface of the second substrate so as to cover at least a part of the first wiring and at least a part of the second substrate,
wherein the first wiring and the second wiring are electrically connected in an overlapping region where the first wiring and the second wiring overlap each other when viewed from the first direction, and
the first protective layer overlaps an entirety of the overlapping region when viewed from the first direction.

2. The stretchable device according to claim 1, wherein the first protective layer covers an entirety of the first wiring.

3. The stretchable device according to claim 1, wherein
the second wiring has a non-overlapping region that does not overlap the first wiring when viewed from the first direction,
the first protective layer overlaps an entirety of the non-overlapping region when viewed from the first direction, and
a first portion of the first protective layer overlapping the non-overlapping region and a second portion of the first protective layer overlapping the overlapping region are continuous when viewed from the first direction.

4. The stretchable device according to claim 1, wherein
the second wiring has a non-overlapping region that does not overlap the first wiring when viewed from the first direction,
the first protective layer overlaps a part of the non-overlapping region when viewed from the first direction, and
a first portion of the first protective layer overlapping the non-overlapping region and a second portion of the first protective layer overlapping the overlapping region are continuous when viewed from the first direction.

5. The stretchable device according to claim 4, wherein when viewed from the first direction, a first protective layer end portion of the first protective layer is between a first end portion on an overlapping region side in an extending direction of the first wiring and a second end portion on a side opposite to the overlapping region in an extending direction of the second wiring.

6. The stretchable device according to claim 1, further comprising a second protective layer extending continuously on the first main surface of the second substrate and a second main surface of the first substrate so as to cover at least a part of the second wiring and at least a part of the first substrate.

7. The stretchable device according to claim 1, further comprising a first insulating layer that covers at least a part of an exposed surface of the first wiring.

8. The stretchable device according to claim 7, further comprising a second insulating layer that covers at least a part of an exposed surface of the second wiring.

9. The stretchable device according to claim 8, further comprising a third insulating layer between the first wiring and the first substrate.

10. The stretchable device according to claim 1, further comprising an insulating layer that covers at least a part of an exposed surface of the second wiring.

11. The stretchable device according to claim 1, further comprising an insulating layer between the first wiring and the first substrate.

12. The stretchable device according to claim 1, further comprising a first coating layer that covers a first main surface side of the first substrate.

13. The stretchable device according to claim 12, further comprising a second coating layer that covers a first main surface side of the second substrate.

14. The stretchable device according to claim 8, further comprising a first coating layer that covers a first main surface side of the first substrate.

15. The stretchable device according to claim 14, further comprising a second coating layer that covers a first main surface side of the second substrate.

16. The stretchable device according to claim 1, further comprising a connection member electrically connecting the first wiring and the second wiring.

17. The stretchable device according to claim 16, wherein
a first part of the connection member is between the first wiring and the second wiring,
a second part of the connection member is outside an end portion of the first wiring so as to cover the end portion of the first wiring, and
a third part of the connection member is between an end portion of the second wiring and the first protective layer so as to cover the end portion of the second wiring.
